(19) United States
(12) Patent Application Publication
(10) Pub. No.: US 2019/0010603 A1
(43) Pub. Date: Jan. 10, 2019

(54) ELECTROSTATIC CHUCKING OF COVER GLASS SUBSTRATES IN A VACUUM COATING PROCESS

(71) Applicant: CORNING INCORPORATED, CORNING, NY (US)

(72) Inventors: Daniel Robert BOUGHTON, Naples, NY (US); James Gerard FAGAN, Painted Post, NY (US)

(73) Assignee: CORNING INCORPORATED, Corning, NY (US)

(21) Appl. No.: 16/067,278

(22) PCT Filed: Dec. 28, 2016
(86) PCT No.: PCT/US2016/068853

§ 371 Date: Jun. 29, 2018

Related U.S. Application Data
(60) Provisional application No. 62/272,372, filed on Dec. 29, 2015.

(51) Int. Cl. C23C 14/50; C23C 14/54; C23C 14/34; H01J 37/32; H01J 37/34; C03C 17/00

(52) U.S. Cl. CPC C23C 14/505; C23C 14/541; C23C 14/34; H01J 37/32724; C03C 2218/154; H01J 37/3488; C03C 17/002; C03C 2217/78; H01J 37/32733

(57) ABSTRACT

A electrostatic chucking apparatus and method for coating mobile device 2D or 3D cover glass in a vacuum coating chamber having a rotating drum and which is driven in rotation. The apparatus includes a carrier including a liquid-cooled cold plate which is removably mountable to the rotating drum. In the case of 3D cover glass, the carrier includes a portion with a 3D profile to match a 3D profile of the 3D cover glass. The carrier further includes an electrostatic chuck (ESC) adapted to secure the cover glass in place against the carrier in the face of centrifugal forces caused by rotation of the rotating drum, with the ESC developing a sufficient clamping force for reliably securing the cover glass in place.

### CROSS-REFERENCE TO RELATED APPLICATIONS

This application claims the benefit of priority under 35 U.S.C. § 119 of U.S. Provisional Application Ser. No. 62/272,372 filed on Dec. 29, 2015, the contents of which is relied upon and incorporated herein by reference in its entirety.

### BACKGROUND OF THE INVENTION

The present invention relates to the general field of chucking or clamping a substantially two-dimensional (flat or 2D) cover glass substrate and/or a substantially three-dimensional (sometimes referred to as curved or 3D) cover glass substrate for the purpose of plasma processing, such as to allow physical vapor deposition by which coatings or treatments are applied to the glass substrate. In particular, the present invention relates to such chucking by means of an induced electrostatic polarization commonly known as electrostatic chucking or “ESC” for short.

Corning Inc. is the leading market supplier to the handheld display glass market and has developed numerous display glass compositions with treatments to meet market demands, such as antimicrobial and anti-scratch coatings. Moreover, a demand for improved scratch-resistant coatings to compete with sapphire glass has developed. Low manufacturing cost and rapid delivery in the highly competitive world of handheld displays is paramount and therefore a low-cost, high-volume manufacturing process for producing high end scratch-resistant coatings is desired for both 2D and 3D cover glass substrates. During such vacuum coating processes, the substrates can reach a significant temperature due to particle kinetics over the process duration. Currently, in production the substrates typically reach a temperature of 230° C. which makes clamping the substrates difficult with conventional techniques, such as adhesive tapes. Currently in manufacturing a double-sided tape method is being used to attach the substrates to the carriers in the coating system. There are three distinct disadvantages to this method: (1) the taping process is labor intensive and increases the time to set up the carriers for the next run and (2) the adhesive outgases in the pristine plasma environment resulting in contamination, requiring the plasma process chamber to be cleaned periodically and adding more cost and time to the process, and, (3) the adhesive leaves residue on the coated glass substrates which requires additional handling and cleaning post-coating, also adding further costs and time to the process.

Several methods to bond glass temporarily for processing have been tried in industry without significant success, such as glass-to-glass van der Waals bonding, adhesive bonding with various adhesive compositions such as a polyimide adhesive tape being currently used in production, polymeric coating on the glass surfaces to change the surface energy resulting in a temporary bond remaining strong enough for the contemplated end process but weak enough to de-bond once the process is complete, etc. These are a few examples of clamping or holding methods and each have their drawbacks. For example, adding a thin film polymerized coating onto a carrier surface to change the surface energy requires a PVD or CVD system to produce the required thin film and is in itself a significantly expensive process. This thin film coating on a carrier needs to be stripped and replaced at certain process run intervals, adding to further cost and complexity.

Electrostatic chucking (“ESC”) is a technology in which a static electric field with planar field lines (produced from a high voltage potential) is applied to parallel electrodes separated by a dielectric and induces molecular dipoles in the (glass) substrate. These molecular dipoles align themselves with the externally-applied electric field and are thus attracted cumulatively to the field lines from the electrodes. Electrostatic chucking has been used in other industries/applications, although it has not been known to be used in PVD coating of glass (it has not been known to be technically feasible for this application).

Japanese patent publication number JP2007036285A describes a high temperature metal sputtering process on a board/substrate (presumably semiconductor wafer from the title) which is clamped by an electrostatic chuck which is heated from 100° C. to 150° C. for the sputtering process.

United States Published Patent Application Number US20140034241A1 describes an electrostatic clamping apparatus in a plasma processing chamber used for plasma etch processing of 3-dimensional SiOG substrates (silicon coated glass substrates) used for stacked microprocessor fabrication.

Japanese published patent application number JP2012124362A describes an electrostatic chuck clamping a glass substrate in a sputtering plasma process while controlling the substrate temperature. The thermal control is accomplished by a broadly used technique in the semiconductor industry of using gas, typically He, flowing in micro-channels on the ESC surface behind the substrate.

The 2006 article by Choe, Hee-Hwan, “Basic Study of a Glass Substrate in a Dry Etching System,” Vacuum 81 (2006) pp. 344-346 discusses the theoretical effect of the electric field from plasma in a reactive ion etch chamber and the backside cooling with He on a glass substrate and the use of an ESC to oppose and overcome these forces.

Accordingly, it can be seen that a need yet remains for a solution for chucking or clamping a substantially two-dimensional (flat or 2D) cover glass substrate and/or a substantially three-dimensional (sometimes referred to as curved or 3D) cover glass substrate for the purpose of plasma processing, such as to allow physical vapor deposition by which coatings or treatments are applied to the glass substrate. It is to the provision of such chucking by means of an induced electrostatic polarization commonly known as electrostatic chucking or “ESC” that the present invention is primarily directed.

### SUMMARY OF THE INVENTION

Briefly described, in a first example form the present invention relates to a chucking apparatus for coating mobile device 3D cover glass in a vacuum coating chamber having a rotating drum and which is driven in rotation. The example apparatus includes a carrier including a liquid-cooled cold plate which is removably mountable to the rotating drum. Preferably, the carrier includes a portion with a 3D profile to match a 3D profile of the 3D cover glass. Moreover, preferably, the carrier further includes an electrostatic chuck (ESC) adapted to secure the 3D cover glass in place against the 3D profile of the carrier in the face of centrifugal forces caused by rotation of the rotating drum in excess of 100 rpm, with the ESC developing a sufficient clamping force for reliably securing the cover glass in place.

In another example form the present invention relates to a chucking apparatus for coating cover glass in a coating chamber having a rotating drum. The apparatus includes a liquid-cooled cold plate removably mountable to the rotating drum and an electrostatic chuck (ESC) secured to the cold plate and adapted to secure the cover glass in place in the face of centrifugal forces caused by rotation of the rotating drum.

Preferably, the ESC develops a clamping force which is a multiple of the centrifugal forces caused by rotation of the rotating drum. More preferably, the ESC develops a clamping force which is at least three times the centrifugal forces caused by rotation of the rotating drum.

Preferably, the cover glass is curved cover glass for hand-held devices and the chucking apparatus further includes a curved adapter mounted between the ESC and the cold plate to match the curvature of the curved cover glass.

Optionally, the ESC can comprise a printed polyimide.

Further, an optional peripheral gasket can be positioned adjacent the ESC to seal edges of the cover glass to the ESC to prevent back sputtering from reaching a back side of the cover glass.

Optionally, the ESC is used in a vacuum chamber in the presence of temperatures in excess of 100 degrees Celsius, while the liquid cooled cold plate is adapted to maintain the temperature of the ESC at 35 degrees Celsius or less.

In yet another example form, the present invention can work with a coating chamber having a large rotating drum over three feet in diameter and which is driven in rotation over 100 rpm. The inventive apparatus can include a liquid-cooled cold plate removably mountable to the large rotating drum and an electrostatic chuck (ESC) secured to the cold plate and adapted to secure the cover glass in place in the face of centrifugal forces caused by rotation of the large rotating drum in excess of 100 rpm. The ESC develops a sufficient clamping force for reliably securing the cover glass in place even in the face of rotation of the large rotating drum.

In yet another example form, the present invention relates to a method for coating mobile device cover glasses in a coating chamber having a large rotating drum driven in rotation during coating. The method comprises the steps of:

a. providing a plurality of carriers for temporarily mounting cover glasses to the rotating drum for coating the cover glasses;

b. providing the carriers with electrostatic chucks (ESCs);

c. mounting cover glasses to the ESCs while the carriers are outside the coating chamber and not mounted to the rotating drum;

d. energizing the ESCs to temporarily secure the cover glasses to the electrostatic chucks and the carriers;

e. mounting the carriers to the rotating drum while the ESCs are temporarily securing the cover glasses;

f. energizing the ESCs to firmly secure the cover glasses to the carriers and thus to the rotating drum despite centrifugal forces caused by rotation of the rotating drum;

g. rotating the rotating drum and coating the cover glasses while the cover glasses are firmly secured to the carriers and to the rotating drum;

h. halting the coating and the rotation of the rotating drum;

i. de-energizing the ESCs;

j. removing the carriers; and

k. removing the cover glasses from the carriers.

Optionally, the ESCs develop a clamping force which is a multiple of the centrifugal forces caused by rotation of the rotating drum. More preferred, the ESCs develop a clamping force which is at least three times the centrifugal forces caused by rotation of the rotating drum.

This method can be used with 2D cover glass or with curved cover glass for hand-held devices. In the case of curved (3D) cover glass, the carriers can include curved adapters to match the curvature of the curved cover glass.

Such a coating method can be used with the ESCs to apply an anti-scratch coating to the cover glass. Moreover, the coating method can optionally be used with a vacuum coating chamber in the presence of temperatures in excess of 100 degrees Celsius, and the method can further include providing the carriers with liquid-cooled cold plates to maintain the temperature of the ESCs at 35 degrees Celsius or less.

In yet another example form, the present invention relates to an improved manufacturing method for coating mobile device cover glasses with a coating in which the coating is applied via a sputtering plasma process in which the cover glasses are temporarily mounted on a rotating drum as the coating is delivered. The improvement therein comprises electrostatically clamping the cover glasses with an ESC to carriers temporarily secured to the rotating drum with a sufficient clamping force to retain the cover glasses in place despite centrifugal forces acting on the cover glasses caused by rotation of the drum, which otherwise would tend to dislodge the cover glasses from the rotating drum as it rotates.

The present invention advantageously provides a method and apparatus for precisely registering and holding a cover glass substrate in position for use in a glass plasma coating process in order to maintain a high degree of coating uniformity, while providing a simple and efficient means to load and unload the processed substrates without undesired residue or damage.

### BRIEF DESCRIPTION OF THE DRAWING FIGURES

FIG. 1 is a schematic illustration of a number of chucking apparatuses for coating cover glass in a coating chamber having a rotating drum according to a first preferred form of the present invention.

FIG. 2 is a schematic, perspective illustration of an illustrative chucking apparatus of FIG. 1, showing a 3-D cover glass mounted thereon.

FIG. 3 is a partially exploded, perspective illustration of an illustrative chucking apparatus of FIG. 2, showing a 3-D cover glass mounted thereon.

FIG. 4 is a schematic, elevation view of an illustrative chucking apparatus of FIG. 1, being tested and showing a 3-D cover glass mounted thereon.

FIG. 5 is a schematic, elevation view of a portion of the chucking apparatus of FIG. 4.

FIG. 6 is a schematic, elevation view of a chucking apparatus showing the chucking of a 2D cover glass according to another illustrative form of the present invention.

FIG. 7 is a schematic, elevation view of the chucking apparatus of FIG. 4 and shown mounted to a test rig.

FIG. 8 is a schematic, elevation view of a portion of the test rig shown in FIG. 7.

FIG. 9 is a schematic, sectional view of another illustrative chucking apparatus according to the present invention, showing a 3-D cover glass mounted thereon.

FIG. 10 is a schematic, elevation view of the chucking apparatus of FIG. 4 and shown mounted to another test rig and undergoing a test.

FIG. 11 is a flow chart of an illustrative method for coating mobile device cover glasses in a coating chamber having a large rotating drum driven in rotation during coating, according to another form of the present invention.

### DETAILED DESCRIPTION

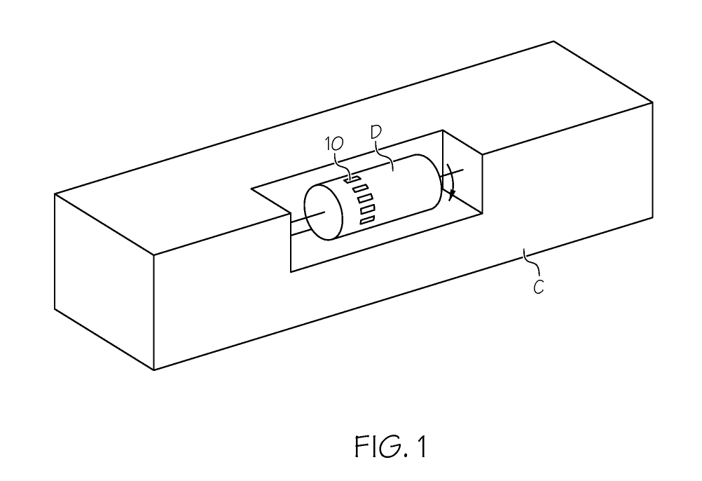

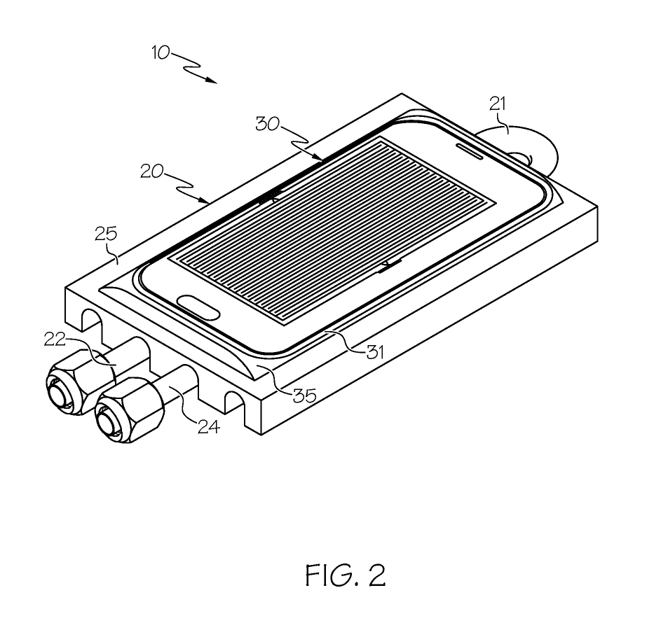

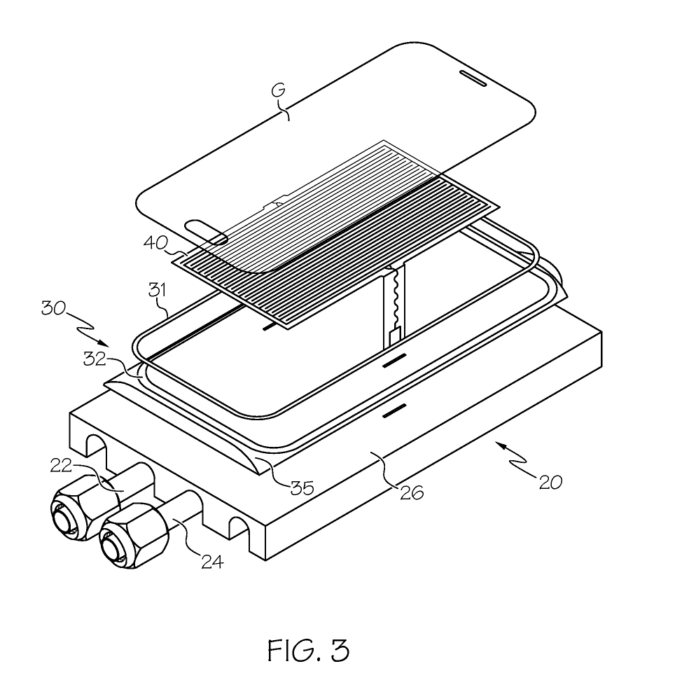

Referring now in detail to the various drawing figures, in which like reference characters represent like parts throughout the several views, FIG. 1 shows a plurality of chucking apparatuses 10 for coating cover glass in a coating chamber C having a rotating drum D. As shown in the subsequent figures, the apparatus 10 includes a roughly rectangular liquid-cooled cold plate 20 removably mountable to the rotating drum D and having a U-shaped cold water line 21 with inlet and outlets 22, 24. Chilled water can be forced through the water line 21 to cool the cold plate 20 in the face of high ambient temperatures, such as typically experienced in PVD coating processes. An electrostatic chuck (ESC) 30 is secured to an upper face 26 of the cold plate 20 and is adapted to secure the cover glass G in place in the face of centrifugal forces caused by rotation of the rotating drum D.

Preferably, the ESC 30 develops a clamping force which is a multiple of the centrifugal forces caused by rotation of the rotating drum D. More preferably, the ESC 30 develops a clamping force which is at least three times the centrifugal forces caused by rotation of the rotating drum D. Optionally, the ESC 30 can comprise a printed polyimide.

Further, an optional peripheral gasket 31 can be emplaced adjacent the edges of the ESC 30 to seal edges of the cover glass G to the ESC 30 to prevent back sputtering from reaching a back side of the cover glass G. Optionally, the ESC 30 includes a base plate or adapter plate 35 which can be mounted to the cold plate 20 and which can be contoured to match the particular contour of the cover glass G. While a cover glass G with a mild curvature at the edges is shown in these figures, those skilled in the art will appreciate that a cover glass with a much greater curvature, or no curvature at all (a flat or 2-D cover glass) can by coated by providing a base plate adapted to the curvature (or lack thereof) of the cover glass. Thus, the base plate acts like an adapter to adapt the ESC 30 to the particular cover glass being processed. The base plate 35 includes a peripheral groove 32 for receiving the resilient gasket 31 therein. The depth of the groove 32 is slightly less than the uncompressed height of the gasket 31 so as to create a bit of “crush” in the gasket as the cover glass G is drawn thereagainst, providing an effective and tight seal near the edges of the glass.

Optionally, the ESC 30 is used in a vacuum chamber C in the presence of temperatures in excess of 100 degrees Celsius, while the liquid-cooled cold plate 20 is adapted to maintain the temperature of the ESC at 35 degrees Celsius or less.

The chuck 10 includes a polyimide ESC 40 adapted to a 3D cover glass. The polyimide ESC 40 is in contact with a flat inner portion of the 3D cover glass G only. As mentioned above, the ESC is provided with a semiconductor plasma-resistant grade back sputter prevention gasket 31.

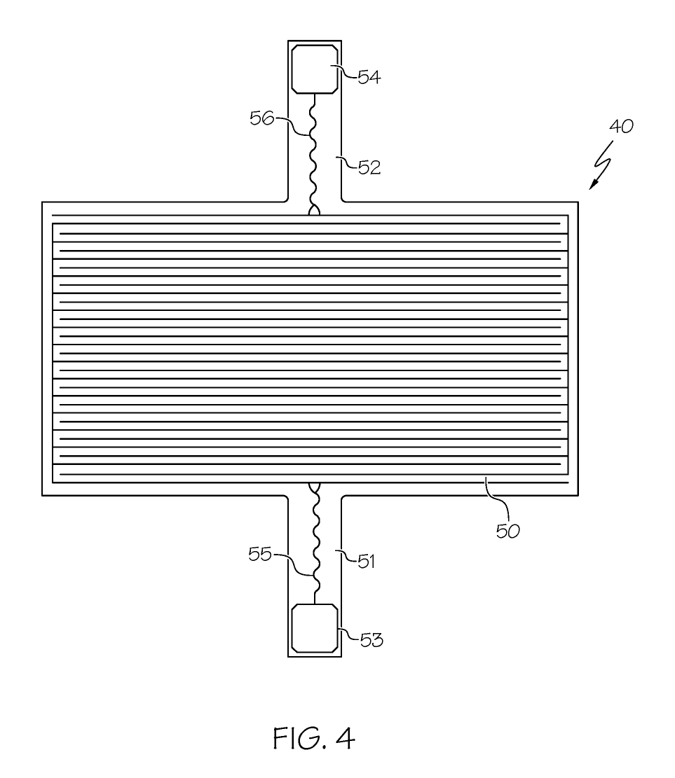

Optionally, as shown in FIG. 4, the polyimide ESC includes a PCB copper layout 50 for the polyimide flex circuit CAD file can be used by PCB (printed circuit board) manufacturer to fabricate the flex circuit. The layout design (pattern) is a commercially-available design for use with polyimide film. The upper and lower leads 51, 52 have copper pads 53, 54 to which high voltage (24 kVDC) and high temperature (250° C.) wires 55, 56 are soldered.

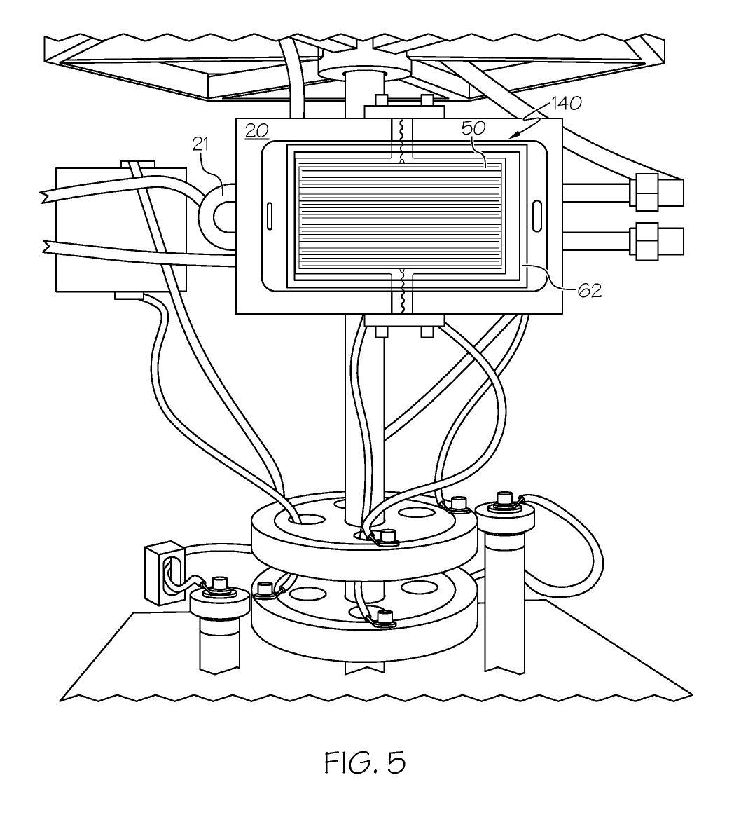

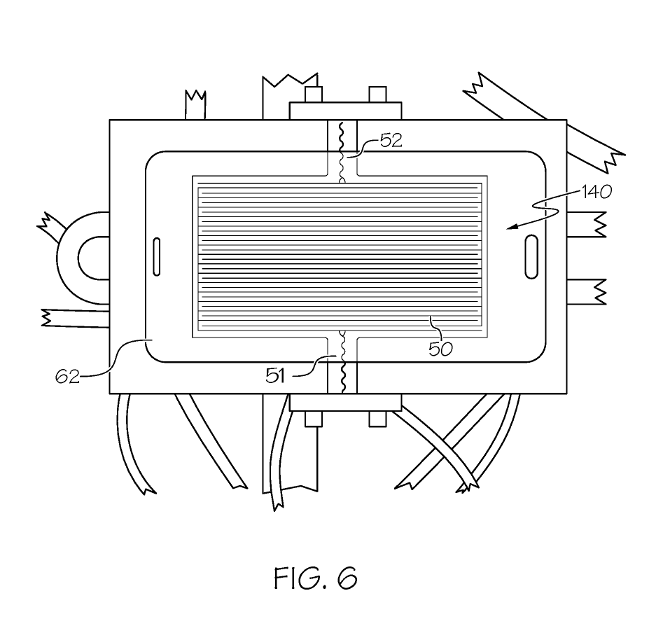

Optionally, as shown in FIGS. 5 to 7, the cover glass can be a 2D cover glass G2. For example, FIG. 6 shows a polyimide ESC 140 with a 2D cover glass substrate G2 chucked to it on a cold plate 20 which keeps the polyimide and the substrate to a maximum 35° C. in a 230° C. oven. To test the performance of this 2D clamping/chucking, three of these ESC's 140 with Corning 5318 IOX cover glass substrates were clamped for three hours while spinning at 210 RPM, producing 10 G's of centrifugal force normal to the substrate surface. This centrifugal force was opposed by the electrostatic field inducing polarization in the glass causing it to be clamped to the ESC surface. Thus, the ESC 140 was more than capable of holding the cover glass fast against the chucking apparatus during such spinning.

As shown in FIG. 6, the 2D decorated cover glass showing polyimide ESC 140 clamps only in clear area of the cover glass G2. In experiments, three cold plates were mounted to a rotating support 35 cm in diameter in a 250° C. oven and spun at 210 RPM with 12.6 g cover glass samples shown in FIG. 6 resulting in a 1.08 N centrifugal force which exceeds the 0.64 N calculated for the drum coater example. So the polyimide ESC's described herein when applied to a drum coater PVD process exceed the required clamping force necessary to keep the cover glass clamped up to a 20 g cover glass size. If >20 g glass samples are used, then the area of the ESC can be increased to have more of the glass area clamped by the ESC.

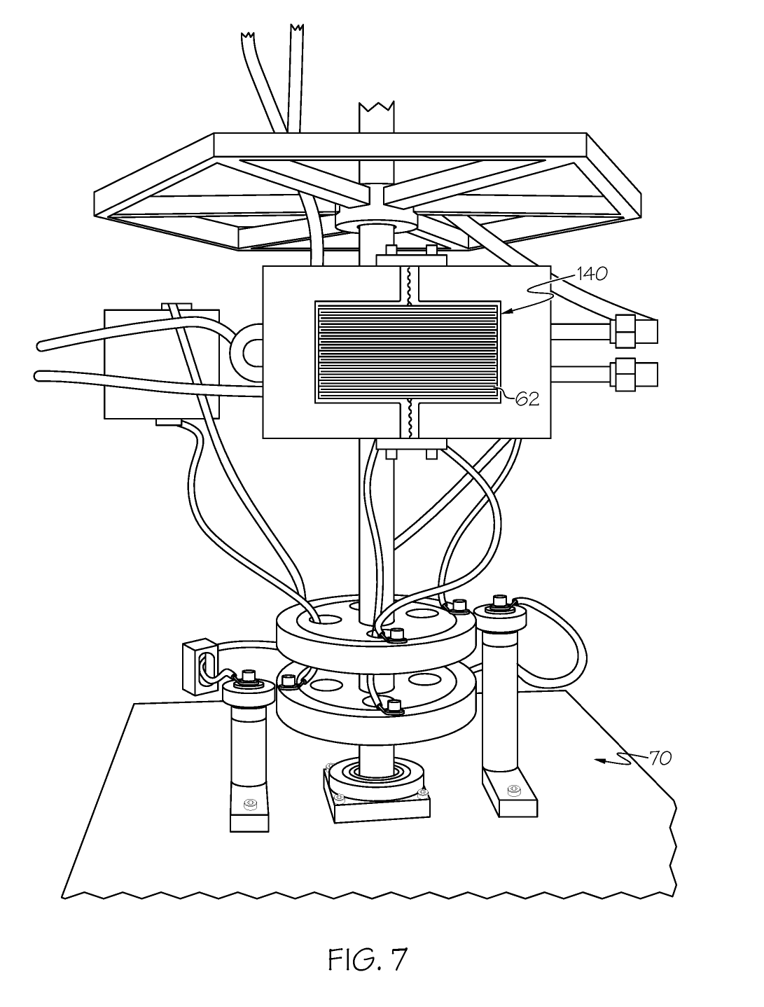

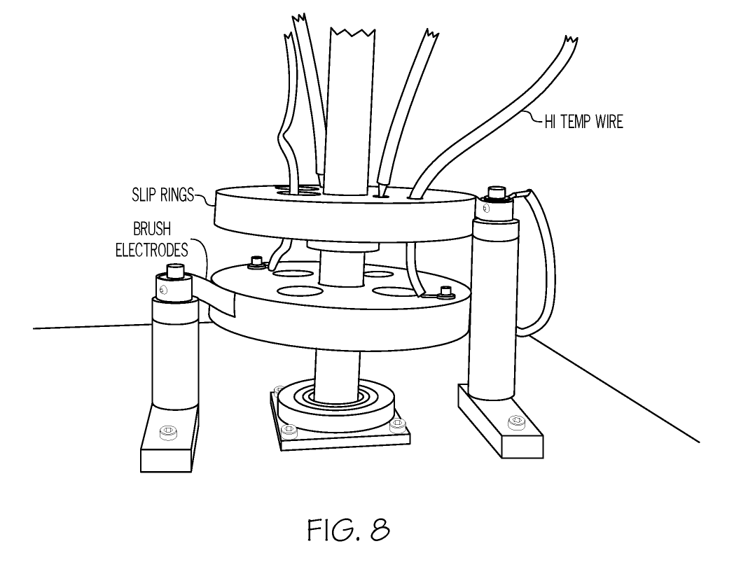

As shown in FIG. 7, a spin rig fixture 70 was used to test the ESCs and the test fixture 70 held three polyimide 2D (can also hold 3D test cold plates) ESC's with cold plates and coolant water circulating from a rotary two port union on the shaft (see the lower part of FIG. 7). FIG. 8 is a close up of the 3.6 kVdc slip ring contacts and 250° C. 25 kVdc rated wire which conveys the charge potential to the ESC's as they spin. This spin rig was placed in a 250° C. oven and the shaft was connected externally to a gear motor which turned the shaft at 210 RPM. This produced a centrifugal force of 0.11 N on a 12.6 g cover glass substrate which mirrored the production rotary coating system. The ESC effectively held the cover glasses in place despite the rotation and the heat.

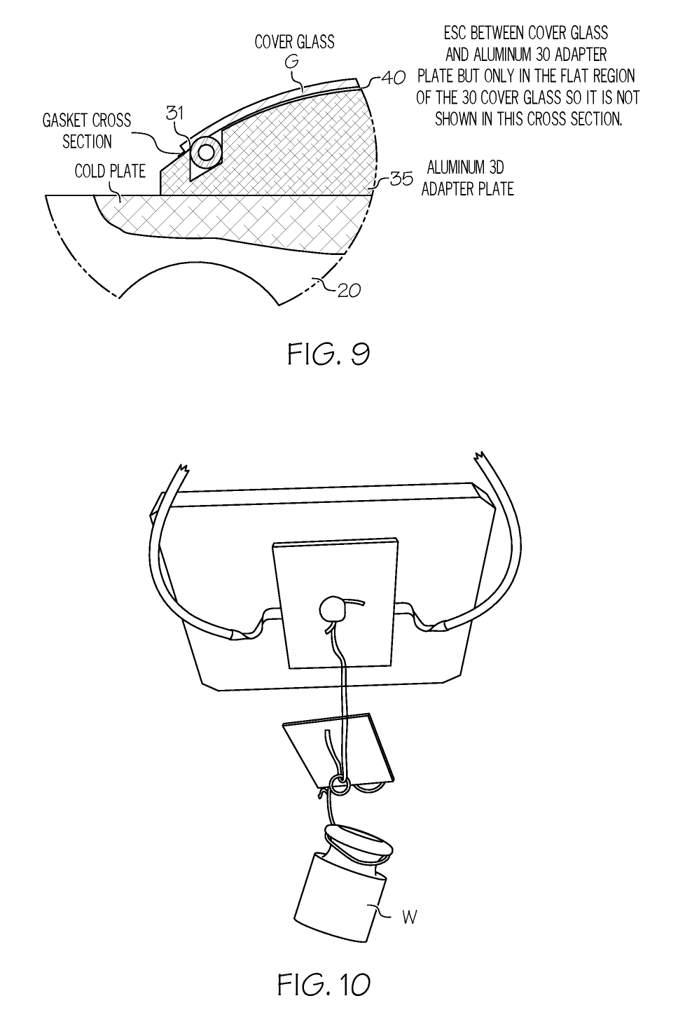

FIG. 9 is a sectional illustration showing a 3D cover glass G mounted to an ESC 40 atop an adapter plate 35 affixed to the cold plate 20. The adapter plate includes a peripheral groove for receiving a compressible gasket 31. In the particular illustrative example shown in this figure, the gasket is a bulb-type with a wing on one side. This shape of gasket thus has a slip feature that provides a wide seal as a 3D cover glass G is compressed on to ESC.

FIG. 10 schematically represents an experiment that was conducted and which established that the polyimide ESC 40 with 3 kVDC applied to it can clamp and hold a Corning 5318 glass sample for 1 hour with a 200 g weight W attached to it.

In yet another example form, the present invention can work with a coating chamber having a large rotating drum over three feet in diameter and which is driven in rotation over 100 rpm. The inventive apparatus can include a liquid-cooled cold plate removably mountable to the large rotating drum and an electrostatic chuck (ESC) secured to the cold plate and adapted to secure the cover glass in place in the face of centrifugal forces caused by rotation of the large rotating drum in excess of 100 rpm. The ESC develops a sufficient clamping force for reliably securing the cover glass in place even in the face of rotation of the large rotating drum.

Optionally, the chucking apparatus for coating mobile device 3D cover glass in a vacuum coating chamber having a rotating drum and which is driven in rotation. The example apparatus includes a carrier including a liquid-cooled cold plate which is removably mountable to the rotating drum. Preferably, the carrier includes a portion with a 3D profile to match a 3D profile of the 3D cover glass. Moreover, preferably, the carrier further includes an electrostatic chuck (ESC) adapted to secure the 3D cover glass in place against the 3D profile of the carrier in the face of centrifugal forces caused by rotation of the rotating drum in excess of 100 rpm, with the ESC developing a sufficient clamping force for reliably securing the cover glass in place.

Preferably, the cover glass is curved cover glass for hand-held devices and the chucking apparatus further includes a curved adapter mounted between the ESC and the cold plate to match the curvature of the curved cover glass.

To facilitate flatness and a high degree of contact between the glass substrate and the ESC, the cold plate can be machined to a flatness of less than 10 μm and a surface roughness of less than 1 μm. To attach the ESC to the cold plate, either a baked-out double-sided tape can be used or a thermal epoxy can be used if the ESC is placed on the uncured epoxy and the cold plate is milled to a high degree of flatness. Such double-sided tape could be, for example, Kapton® tape (tape having Kapton® polyimide from DuPont). The doubled-sided tape is first baked at 200° C. for 1 hour to evaporate off the silicone oil normally used in the adhesive. This prevents the oil from vaporizing and then condensing on the cold plate and cover glass during the coating process. Once baked, the doubled-sided tape is rolled onto the polyimide ESC backside and then both are rolled on to the cold plate. In the case of the 3D part it would be rolled onto the cold plate aluminum 3D adapter plate. To prevent mechanical stress on the soldered joints of the ESC, the lead is placed between a clamping mechanism made from dielectric material so as to not provide an electrical arc path and short out the ESC.

Additional double-sided tape may be used around the solder joint to provide increased insulation protection. It is important that no air bubbles be trapped under the ESC or the double-sided tape since the ESC is used in a high vacuum plasma environment (1×10-4 Torr). Under vacuum, an air bubble would greatly expand and cause the cover glass substrate to debond from the ESC.

In both the 2D and 3D cover glass ESC/cold plate assembly a gasket is used to seal the edge of the cover glass backside so that back sputter is prevented. These gaskets have a flipper strip along their length as shown in the cross-section in FIG. 8. When the cover glass is compressed on the gasket by the clamping force of the ESC, the flipper folds down on the inside edge of the cover glass forming a tight wide seal around its perimeter. The same mechanism is used on the flat 2D cover glass.

For supplying electric power, a 3 kVdc ESC power supply was designed and fabricated consisting of a lithium ion battery and a 12 Vdc to 3 kVdc high voltage module with no polarity switching. A 3 kVdc ESC power supply was designed and fabricated consisting of a lithium ion battery and a 12 Vdc to 3 kVdc high voltage module with high voltage polarity switching to prevent permanent polarization in the cover glass substrate. Both power supplies were used for experiments with the polyimide ESC.

The power supply used in the prototype was made from a lithium ion rechargeable battery and a commercially available high voltage DC to DC converter which takes 12 VDC and steps it up to 3 kVDC. A second power supply was also used which incorporated a timer circuit to switch the high voltage output polarity every 13 minutes to prevent permanent polarization of the cover glass substrate during the coating process. In addition, any high voltage DC supply may be used with the polyimide ESC where the potential is 3.6 kVDC. The current to be supplied for a typical process load of 180 cover glass samples with a power module on groups of three ESC's with one ESC for each cover glass and the current draw by each module is 300 mA is 180/3=60 modules×300 mA=18 A. A single 12 VDC 20A power supply would power all of the 180 ESC's. To prevent permanent polarization of the molecules in the cover glass substrate with a process temperature of 250° C. and an electric field of 3.6 kVDC, a time varying arbitrary waveform which alters the orientation of the field may be used. In addition, as has been noted the polarity of the high voltage on the ESC may be reversed periodically as well.

To keep the polyimide from degrading thermally and to keep the substrate cool, the cold plate is connected to a chiller which circulates coolant water through the cold plate which keeps it between 23° C. and 35° C. Experiments were run that kept the ESC at 35° C. in a 230° C. oven and after dozens of experiments no degradation of the polyimide was seen.

Experiments with electrostatically chucked glass in a PVD coating process with dielectric, oxide, metals, and semiconductor coatings showed no effect on coating uniformity or deposition rate at very thin coating levels of about 50 nm and thin coating levels of about 200 nm.

To load the cover glass substrates into the coating vacuum chamber, a carrier with the ESC's mounted on them may be energized by a power supply and the cover glass substrates placed on the ESC's. The power may be shut off and supply disconnected from the ESC's and a temporary bonding of the cover glass substrate results and may be sustained for up to two hours while the carriers are loaded or unloaded from the coating system. Once loaded on to the rotary drum, the ESC's may be connected once again to the power supply and remain energized during the coating process to ensure the cover glass samples have enough clamping force applied to them while the drum rotates.

In use, the equipment is centered on the ESC which is commercially fabricated from a polyimide film stack with interdigital copper electrodes sandwiched between a top and lower polyimide film. Copper leads are brought out as shown in the figures. The leads are encapsulated in polyimide which acts as an insulating dielectric. The leads are terminated in copper pads to which the high voltage high temperature wire is soldered to connect the ESC to the power supply. Undulating copper traces are added to the leads to allow flexibility without cracking the thin copper foil when the leads are bent around the edges of the cold plates. Alternatively, the cold plates could be provided with smoothly radiused edges to avoid sharp corners (bends) in the copper foils in the vicinity of the leads.

In a prototype, the ESC electrode area was designed to be 10.0 cm×5.5 cm with a square area of 55 cm². To test the clamping force a 7.73 g sample of Corning 5318 cover glass was cut to 10 cm×5.5 cm and a thin wire hook was hot glued to the center of the substrate. The ESC on the cold plate was clamped upside down so that the wire hung down and the high voltage 3 kVDC supply was connected to the ESC. Laboratory weights were hung on the hook to evaluate loads that potentially would cause the glass to be debonded from the ESC. A total of 200 g was hung on the electrode and remained for the duration of the test which was 1 hour. Not counting the weight of the glue and hook, the ratio of the weight hung on the sample to the weight of the glass was 200 g/7.73 g=>25 G or a clamping force equivalent to 25.9 times the weight of the glass. A drum coater may for instance have a drum diameter of 1.5 m and may spin at 100 RPM. The circumference is then 4.7 m and the RPS=100/60=1.7 RPS, then the velocity, v=4.7 m/1.7 RPS=2.8 m/s which is the linear velocity. The centrifugal force is then:

For the 7.73 g cover glass:

Fc=m(nω/60)2/r=7.73×10−3 kg (100*2*π*0.75m/60)2/0.75m=0.64 N

If the contact area is 5.5 cm×10 cm or 55 cm2 then the area=0.0055 m2 then

0.64/0.0055 m2=115.6 N/m2=1.18 g/cm2

which is the minimum bond strength to hold the part as it spins on the outside of a 1.5 m diameter drum rotating at 100 RPM. In the experiment above we have a combined weight of 207.73 g with a contact area of 10 cm×5.5 cm or 55 cm2. 207.73 g/55 cm2=3.78 g/cm2 with a 3 kVDC field on the ESC. 3.87 g/cm2/1.18 g/cm2=3.3 times the clamping force needed for use on the drum coater with the conditions noted above.

While electrostatic chucking is not new generally, heretofore it has not been known to be used on cover glass substrates in a plasma vacuum coating involving high temperatures. The present invention allows electrostatic chucking to be employed in such an application, in part by mitigating the working temperature of the electrostatic chuck by active cooling thereof. This facilitates clamping either a 2D or 3D cover glass substrate with a >10 G holding force, allowing it to be held during a spinning coating operation where the centrifugal force opposes the electrostatic clamping force. Heretofore, this has not been accomplished in the industry.

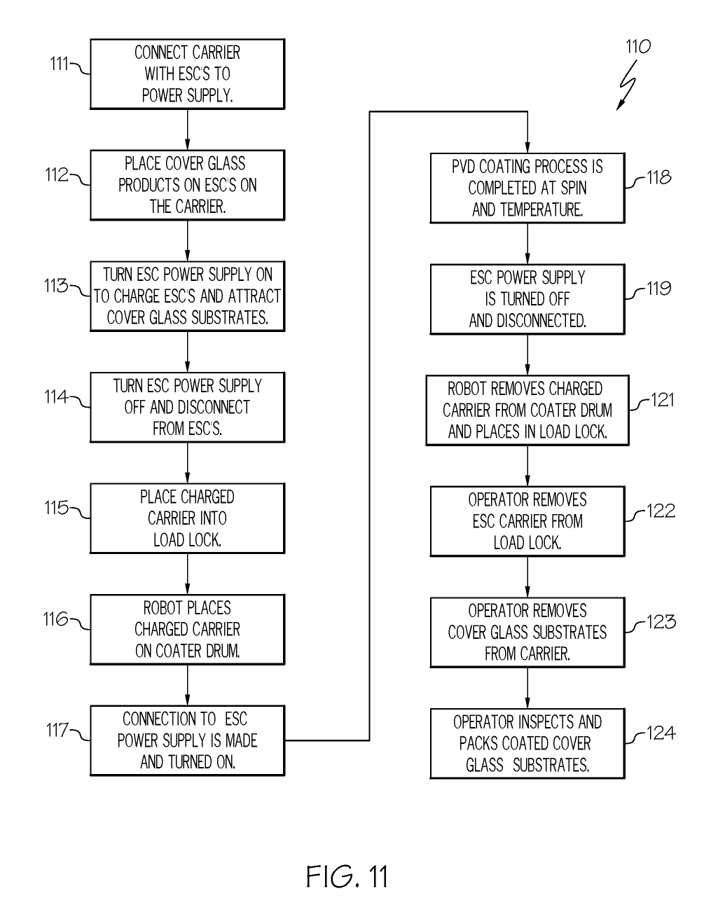

In yet another example form as shown in FIG. 11, the present invention relates to a method 110 for coating mobile device cover glasses in a coating chamber having a large rotating drum driven in rotation during coating. The method generally comprises the steps of:

providing a plurality of carriers for temporarily mounting cover glasses to the rotating drum for coating the cover glasses;

providing the carriers with electrostatic chucks (ESCs);

mounting cover glasses to the ESCs while the carriers are outside the coating chamber and not mounted to the rotating drum;

energizing the ESCs to temporarily secure the cover glasses to the electrostatic chucks and the carriers;

mounting the carriers to the rotating drum while the ESCs are temporarily securing the cover glasses;

energizing the ESCs to firmly secure the cover glasses to the carriers and thus to the rotating drum despite centrifugal forces caused by rotation of the rotating drum;

rotating the rotating drum and coating the cover glasses while the cover glasses are firmly secured to the carriers and to the rotating drum;

halting the coating and the rotation of the rotating drum;

de-energizing the ESCs;

removing the carriers; and

removing the cover glasses from the carriers.

As shown in FIG. 11, the method 110 can include the steps of:

111: connecting a plurality of carriers to electric power, the carriers having ESCs for temporarily mounting cover glasses to the rotating drum for coating the cover glasses;

112: mounting cover glasses to the ESCs while the carriers are outside the coating chamber and not mounted to the rotating drum;

113: energizing the ESCs to temporarily secure the cover glasses to the electrostatic chucks and the carriers;

114: de-energizing the ESCs;

115 and 116: mounting the carriers to the rotating drum while the ESCs are temporarily securing the cover glasses (placing the carriers into a load lock and robotically placing the carriers onto the coater drum);

117: energizing the ESCs to firmly secure the cover glasses to the carriers and thus to the rotating drum despite centrifugal forces caused by rotation of the rotating drum;

118: rotating the rotating drum and coating the cover glasses while the cover glasses are firmly secured to the carriers and to the rotating drum, and halting the coating and the rotation of the rotating drum;

119: de-energizing the ESCs;

121-122: removing the carriers from the drum and from the load lock;

123: removing the cover glasses from the carriers; and

124: inspecting and packing the cover glasses.

Optionally, the ESCs develop a clamping force which is a multiple of the centrifugal forces caused by rotation of the rotating drum. More preferred, the ESCs develop a clamping force which is at least three times the centrifugal forces caused by rotation of the rotating drum.

This method can be used with 2D cover glass or with curved (3D) cover glass for hand-held devices. In the case of curved (3D) cover glass, the carriers can include curved adapters to match the curvature of the curved cover glass, as described above.

Such a coating method can be used with the ESCs to apply an anti-scratch coating to the cover glass. Moreover, the coating method can optionally be used with a vacuum coating chamber in the presence of temperatures in excess of 100 degrees Celsius, and the method can further include providing the carriers with liquid-cooled cold plates to maintain the temperature of the ESCs at relatively low working temperatures, such as 35 degrees Celsius or less.

In yet another example form, the present invention relates to an improved manufacturing method for coating mobile device cover glasses with a coating in which the coating is applied via a sputtering plasma process in which the cover glasses are temporarily mounted on a rotating drum as the coating is delivered. The improvement therein comprises electrostatically clamping the cover glasses with an ESC to carriers temporarily secured to the rotating drum with a sufficient clamping force to retain the cover glasses in place despite centrifugal forces acting on the cover glasses caused by rotation of the drum, which otherwise would tend to dislodge the cover glasses from the rotating drum as it rotates.

### Some Advantages

The electrostatic chucking of cover glass substrates in a coater is a clean technology which does not leave any residue on the processed cover glass necessitating cleaning post-process. The electrostatic chucking of cover glass substrates in a coater has a very low labor expenditure (seconds compared with 10's of minutes for the current taping process), permitting rapid loading and unloading into the coating chamber. Water cooling keeps the polyimide and cover glass substrate close to room temperature, so the polyimide ESC has a long service life and several use cycles and does not age from exposure to the cumulative process temperature rise on the cover glass substrate.

The polyimide ESC is easily manufactured by various printed circuit board fabrication houses with a photo patterning method and is very low cost ($10's to $100's), compared to commercially designed and fabricated ESC's ($1,000's) and the delivery time for a polyimide ESC is in days (5 typical), while commercially designed ESC's have months for delivery. The polyimide ESC is a made from a thin (0.13 mm) film, is flexible, and can be adapted to a contoured surface, making it an ideal clamping mechanism for a 3D cover glass substrate.

The present invention advantageously provides a method and apparatus for precisely registering and holding a cover glass substrate in position for use in a glass plasma coating process in order to maintain a high degree of coating uniformity, while providing a simple and efficient means to load and unload the processed substrates without undesired residue or damage.

The handheld display glass electrostatic chucking method and apparatus described herein provides a low-cost processing capability by permitting a simple retrofit of existing plasma thin film deposition systems, while not being adversely impacted by the high temperature typically experienced therein.

While the invention has been described in terms of preferred illustrative embodiments, those skilled in the art will appreciate that various changes, additions, deletions, and modifications can be made therein without departing from the spirit and scope of the invention as defined in the appended claims. Some exemplary embodiments include the following.

### Embodiment 1

A chucking apparatus for coating mobile device 3D cover glass in a vacuum coating chamber having a rotating drum and which is driven in rotation, the apparatus comprising:
a carrier including a liquid-cooled cold plate and being removably mountable to the rotating drum;
the carrier including a portion with a 3D profile to match a 3D profile of the 3D cover glass; and
the carrier further including an electrostatic chuck (ESC) adapted to secure the 3D cover glass in place against the 3D profile of the carrier in the face of centrifugal forces caused by rotation of the rotating drum in excess of 100 rpm, the ESC developing a sufficient clamping force for reliably securing the cover glass in place.

### Embodiment 2

A chucking apparatus for coating cover glass in a coating chamber having a rotating drum, the apparatus comprising:
a liquid-cooled cold plate removably mountable to the rotating drum; and
an electrostatic chuck (ESC) secured to the cold plate and adapted to secure the cover glass in place in the face of centrifugal forces caused by rotation of the rotating drum.

### Embodiment 3

chucking apparatus as in Embodiment 1 or Embodiment 2 wherein the ESC develops a clamping force which is a multiple of the centrifugal forces caused by rotation of the rotating drum.

### Embodiment 4

A chucking apparatus as in Embodiment 1 or Embodiment 2 wherein the ESC develops a clamping force which is at least three times the centrifugal forces caused by rotation of the rotating drum.

### Embodiment 5

A chucking apparatus as in any one of the preceding Embodiments wherein the cover glass is curved cover glass for hand-held devices and wherein the chucking apparatus further includes a curved adapter mounted between the ESC and the cold plate to match the curvature of the curved cover glass.

### Embodiment 6

A chucking apparatus as in any one of the preceding Embodiments wherein the ESC comprises a printed polyimide.

### Embodiment 7

A chucking apparatus as in any one of the preceding Embodiments further comprising a peripheral gasket positioned adjacent the ESC to seal edges of the cover glass to the ESC to prevent back sputtering from reaching a back side of the cover glass.

### Embodiment 8

A chucking apparatus as in any one of the preceding Embodiments wherein the ESC is used to apply an anti-scratch coating to the cover glass.

### Embodiment 9

A chucking apparatus as in any one of the preceding Embodiments wherein the ESC is used in a vacuum chamber in the presence of temperatures in excess of 100 degrees Celsius.

### Embodiment 10

A chucking apparatus as in Embodiment 9 wherein the liquid cooled cold plate is adapted to maintain the temperature of the ESC at 35 degrees Celsius or less.

### Embodiment 11

A chucking apparatus for coating mobile device cover glass in a coating chamber having a large rotating drum over three feet in diameter and which is driven in rotation over 100 rpm, the apparatus comprising:
a liquid-cooled cold plate removably mountable to the large rotating drum; and
an electrostatic chuck (ESC) secured to the cold plate and adapted to secure the cover glass in place in the face of centrifugal forces caused by rotation of the large rotating drum in excess of 100 rpm, the ESC developing a sufficient clamping force for reliably securing the cover glass in place.

### Embodiment 12

A method for coating mobile device cover glasses in a coating chamber having a large rotating drum driven in rotation during coating, the method comprising the steps of:
a. providing a plurality of carriers for temporarily mounting cover glasses to the rotating drum for coating the cover glasses;
b. providing the carriers with electrostatic chucks (ESCs);
c. mounting cover glasses to the ESCs while the carriers are outside the coating chamber and not mounted to the rotating drum;
d. energizing the ESCs to temporarily secure the cover glasses to the electrostatic chucks and the carriers;
e. mounting the carriers to the rotating drum while the ESCs are temporarily securing the cover glasses;
f. energizing the ESCs to firmly secure the cover glasses to the carriers and thus to the rotating drum despite centrifugal forces caused by rotation of the rotating drum;
g. rotating the rotating drum and coating the cover glasses while the cover glasses are firmly secured to the carriers and to the rotating drum;
h. halting the coating and the rotation of the rotating drum;
i. de-energizing the ESCs;
j. removing the carriers; and
k. removing the cover glasses from the carriers.

### Embodiment 13

A coating method as in Embodiment 12 wherein the ESCs develop a clamping force which is a multiple of the centrifugal forces caused by rotation of the rotating drum.

### Embodiment 14

A coating method as in Embodiment 12 or Embodiment 13 wherein the ESCs develop a clamping force which is at least three times the centrifugal forces caused by rotation of the rotating drum.

### Embodiment 15

A coating method as in any one of Embodiments 12-14 wherein the ESCs wherein the cover glass is curved cover glass for hand-held devices and wherein the carriers further include curved adapters to match the curvature of the curved cover glass.

### Embodiment 16

A coating method as in any one of Embodiments 12-15 wherein the ESCs comprise printed polyimide.

### Embodiment 17

A coating method as in any one of Embodiments 12-16 wherein the carriers include a peripheral gasket positioned adjacent the ESC to seal edges of the cover glass to the ESC to prevent back sputtering from reaching a back side of the cover glass.

### Embodiment 18

A coating method as in any one of Embodiments 12-17 wherein the ESCs are used to apply an anti-scratch coating to the cover glass.

### Embodiment 19

A coating method as in any one of Embodiments 12-18 wherein the ESCs are used with a vacuum coating chamber in the presence of temperatures in excess of 100 degrees Celsius, the method further comprising providing the carriers with liquid-cooled cold plates to maintain the temperature of the ESCs at 35 degrees Celsius or less.

### Embodiment 20

In a manufacturing method for coating mobile device cover glasses with a coating in which the coating is applied via a sputtering plasma process in which the cover glasses are temporarily mounted on a rotating drum as the coating is delivered, the improvement therein comprising:
electrostatically clamping the cover glasses with an ESC to carriers temporarily secured to the rotating drum with a sufficient clamping force to retain the cover glasses in place despite centrifugal forces acting on the cover glasses caused by rotation of the drum, which otherwise would tend to dislodge the cover glasses from the rotating drum as it rotates.

### Embodiment 21

A method as in Embodiment 20 wherein the ESC develops a clamping force which is a multiple of the centrifugal forces caused by rotation of the rotating drum.

1. A chucking apparatus for coating mobile device 3D cover glass in a vacuum coating chamber having a rotating drum and which is driven in rotation, the apparatus comprising:
a carrier including a liquid-cooled cold plate and being removably mountable to the rotating drum;
the carrier including a portion with a 3D profile to match a 3D profile of the 3D cover glass; and
the carrier further including an electrostatic chuck (ESC) adapted to secure the 3D cover glass in place against the 3D profile of the carrier in the face of centrifugal forces caused by rotation of the rotating drum in excess of 100 rpm, the ESC developing a sufficient clamping force for reliably securing the cover glass in place.

2. (canceled)

3. A chucking apparatus as claimed in claim 1 wherein the ESC develops a clamping force which is a multiple of the centrifugal forces caused by rotation of the rotating drum.

4. A chucking apparatus as claimed in claim 1 wherein the ESC develops a clamping force which is at least three times the centrifugal forces caused by rotation of the rotating drum.

5. A chucking apparatus as claimed in claim 1 wherein the cover glass is curved cover glass for hand-held devices and wherein the chucking apparatus further includes a curved adapter mounted between the ESC and the cold plate to match the curvature of the curved cover glass.

6. A chucking apparatus as claimed in claim 1 wherein the ESC comprises a printed polyimide.

7. A chucking apparatus as claimed in claim 1 further comprising a peripheral gasket positioned adjacent the ESC to seal edges of the cover glass to the ESC to prevent back sputtering from reaching a back side of the cover glass.

8. A chucking apparatus as claimed in claim 1 wherein the ESC is used to apply an anti-scratch coating to the cover glass.

9. A chucking apparatus as claimed in claim 1 wherein the ESC is used in a vacuum chamber in the presence of temperatures in excess of 100 degrees Celsius.

10. A chucking apparatus as claimed in claim 9 wherein the liquid cooled cold plate is adapted to maintain the temperature of the ESC at 35 degrees Celsius or less.

11. (canceled)

12. A method for coating mobile device cover glasses in a coating chamber having a large rotating drum driven in rotation during coating, the method comprising the steps of:
a. providing a plurality of carriers for temporarily mounting cover glasses to the rotating drum for coating the cover glasses;
b. providing the carriers with electrostatic chucks (ESCs);
c. mounting cover glasses to the ESCs while the carriers are outside the coating chamber and not mounted to the rotating drum;
d. energizing the ESCs to temporarily secure the cover glasses to the electrostatic chucks and the carriers;
e. mounting the carriers to the rotating drum while the ESCs are temporarily securing the cover glasses;
f. energizing the ESCs to firmly secure the cover glasses to the carriers and thus to the rotating drum despite centrifugal forces caused by rotation of the rotating drum;
g. rotating the rotating drum and coating the cover glasses while the cover glasses are firmly secured to the carriers and to the rotating drum;
h. halting the coating and the rotation of the rotating drum;
i. de-energizing the ESCs;
j. removing the carriers; and
k. removing the cover glasses from the carriers.

13. A coating method as claimed in claim 12 wherein the ESCs develop a clamping force which is a multiple of the centrifugal forces caused by rotation of the rotating drum.

14. A coating method as claimed in claim 12 wherein the ESCs develop a clamping force which is at least three times the centrifugal forces caused by rotation of the rotating drum.

15. A coating method as claimed in claim 12 wherein the ESCs wherein the cover glass is curved cover glass for hand-held devices and wherein the carriers further include curved adapters to match the curvature of the curved cover glass.

16. A coating method as claimed in claim 12 wherein the ESCs comprise printed polyimide.

17. A coating method as claimed in claim 12 wherein the carriers include a peripheral gasket positioned adjacent the ESC to seal edges of the cover glass to the ESC to prevent back sputtering from reaching a back side of the cover glass.

18. A coating method as claimed in claim 12 wherein the ESCs are used to apply an anti-scratch coating to the cover glass.

19. A coating method as claimed in claim 12 wherein the ESCs are used with a vacuum coating chamber in the presence of temperatures in excess of 100 degrees Celsius, the method further comprising providing the carriers with liquid-cooled cold plates to maintain the temperature of the ESCs at 35 degrees Celsius or less.

20. In a manufacturing method for coating mobile device cover glasses with a coating in which the coating is applied via a sputtering plasma process in which the cover glasses are temporarily mounted on a rotating drum as the coating is delivered, the improvement therein comprising:
electrostatically clamping the cover glasses with an ESC to carriers temporarily secured to the rotating drum with a sufficient clamping force to retain the cover glasses in place despite centrifugal forces acting on the cover glasses caused by rotation of the drum, which otherwise would tend to dislodge the cover glasses from the rotating drum as it rotates.

21. An improved manufacturing method as claimed in claim 20 wherein the ESC develops a clamping force which is a multiple of the centrifugal forces caused by rotation of the rotating drum.
